(19) United States
(12) Patent Application Publication
(10) Pub. No.: US 2011/0092032 A1
(43) Pub. Date: Apr. 21, 2011

(54) MANUFACTURING METHOD OF SEMICONDUCTOR DEVICE

(75) Inventors: Jae Bon Koo, Daejeon (KR); Seung Youl Kang, Deajeon (KR)

(73) Assignee: ELECTRONICS AND TELECOMMUNICATIONS RESEARCH INSTITUTE, Daejeon (KR)

(21) Appl. No.: 12/766,958

(22) Filed: Apr. 26, 2010

(30) Foreign Application Priority Data
Oct. 15, 2009 (KR) 10-2009-0098243

(51) Int. Cl. H01L 21/336

(52) U.S. Cl. 438/151; 257/E21.411

(57) ABSTRACT

Provided is a manufacturing methods of a semiconductor device. The methods includes: forming an active layer on a first substrate; bonding a top surface of the active layer with a second substrate and separating the active layer from the first substrate; forming conductive impurity regions corresponding to source and drain regions of the active layer bonded on the second substrate; bonding a third substrate on a bottom surface of the active layer and removing the second substrate; and forming a gate electrode on a top between the conductive impurity regions of the active layer bonded on the third substrate and forming source and drain electrodes on the conductive impurity regions.

### CROSS-REFERENCE TO RELATED APPLICATIONS

This U.S. non-provisional patent application claims priority under 35 U.S.C. §119 of Korean Patent Application No. 10-2009-0098243, filed on Oct. 15, 2009, the entire contents of which are hereby incorporated by reference.

### BACKGROUND OF THE INVENTION

The present invention disclosed herein relates to a manufacturing method of a semiconductor device, and more particularly, to a manufacturing method of a semiconductor device that includes a thin film transistor on a plastic substrate.

In general, an organic thin film transistor (OTFT) is extensively used in flexible display driving devices or radio frequency identification (RFID) application devices. When the OTFT uses an organic as a channel layer, defective conduction mechanism and crystallization may occur. Therefore, it is difficult to realize the electron mobility of more than 1 cm²/Vs in the OTFT. Nevertheless, the OTFT is still used to realize a flexible electronic device. In addition, the OTFT has short durability and less driving reliability when being exposed to the atmosphere. Therefore, its commercialization is difficult

For that reason, there is one suggested plan that a typical silicon substrate semiconductor is separated from a glass substrate or a wafer substrate, and then transferred into a plastic substrate. This suggested plan is due to a technical dead end of the OTFT having limited durability and reliability and also increased demands about a high-speed flexible device for a special purpose.

### SUMMARY OF THE INVENTION

The present invention provides a semiconductor manufacturing method that can increase or maximize a yield rate of production by completing the formation of a thin film transistor on a plastic substrate.

Embodiments of the present invention provide manufacturing methods of a semiconductor device, the methods including: forming an active layer on a first substrate; bonding a top surface of the active layer with a second substrate and separating the active layer from the first substrate; forming conductive impurity regions corresponding to source and drain regions of the active layer bonded on the second substrate; bonding a third substrate on a bottom surface of the active layer and removing the second substrate; and forming a gate electrode on a top between the conductive impurity regions of the active layer bonded on the third substrate and forming source and drain electrodes on the conductive impurity regions.

In some embodiments, the forming of the active layer may include forming an ion implantation layer of a predetermined depth in the first substrate.

In other embodiments, the methods may further include forming the gate electrode on the active layer after the forming of the ion implantation layer.

In still other embodiments, the methods may further include forming the gate insulation layer between the active layer and the gate electrode.

In even other embodiments, the gate electrode may include titanium or titanium nitride.

In yet other embodiments, the separating of the active layer may include performing a thermal treatment process on the ion implantation layer.

In further embodiments, the bonding of the top surface of the active layer with the second substrate may include interposing a first insulation layer between the top surface of the active layer and the second substrate.

In still further embodiments, the first insulation layer may not be removed when the second substrate is removed and the remaining first insulation layer may be used as a gate insulation layer.

In even further embodiments, a bottom surface of the active layer and the third substrate may be bonded using an adhesive layer.

In yet further embodiments, the methods may further include islanding thin film transistors including the gate electrode, the source electrode, and the drain electrode, the gate electrode being disposed on the active layer on the third substrate.

In yet further embodiments, the methods may further include forming a second insulation layer on the active layer and the third substrate.

In yet further embodiments, the methods may further include forming a contact plug, the contact plug penetrating through the second insulation layer and connecting the conductive impurity regions and the source and drain electrodes.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 to 11 are manufacturing sectional views illustrating a manufacturing method of a semiconductor device according to a first embodiment of the present invention; and

FIGS. 12 to 22 are manufacturing sectional views illustrating a manufacturing method of a semiconductor device according to a second embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the specification, these terms are only used to distinguish one element from another element. It will also be understood that when a layer (or film) is referred to as being ‘on’ another layer or substrate, it can be directly on the other layer or substrate, or intervening layers may also be present. In the figures, the dimensions of layers and regions are exaggerated for clarity of illustration. Also, though terms like a first and a second are used to describe various members, components, regions, layers, and/or portions in various embodiments of the present invention, the members, components, regions, layers, and/or portions are not limited to these terms. An embodiment described and exemplified herein includes a complementary embodiment thereof.

Hereinafter, a manufacturing method of a semiconductor device according to embodiments of the present invention is described in conjunction with the accompanying drawings.

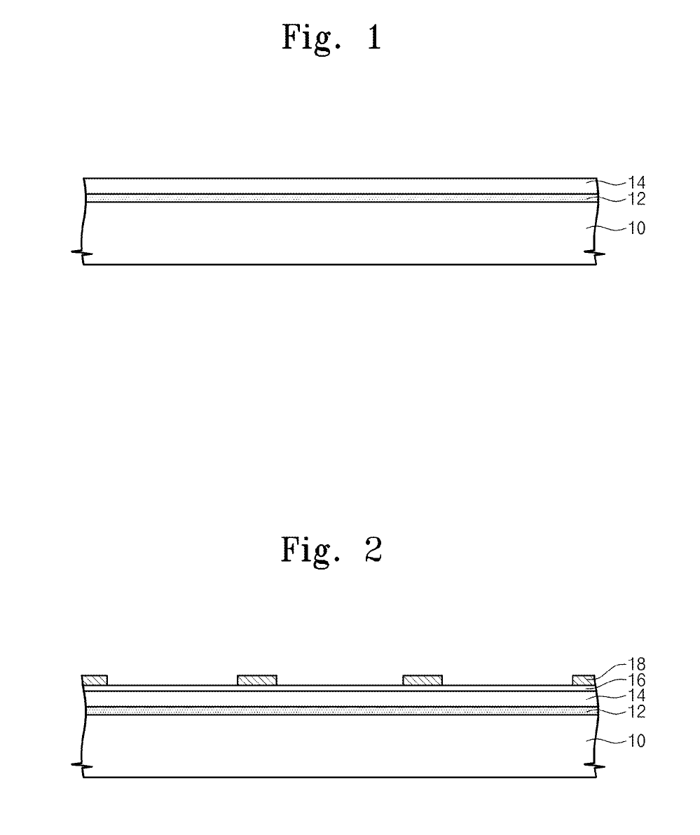

FIGS. 1 to 11 are manufacturing sectional views illustrating a manufacturing method of a semiconductor device according to a first embodiment of the present invention.

Referring to FIG. 1, according to the semiconductor manufacturing method of the first embodiment, hydrogen ions are implanted on a first substrate 10 formed of single crystal silicon so that an ion implantation layer 12 is formed in the first substrate 10. Here, an ion implantation process of the hydrogen ions is performed typically by an implanter. The implanter ionizes hydrogen using an electric energy and accelerates the ionized hydrogen to collide with a target (i.e., the first substrate 10). Therefore, the ion implantation layer 12 is formed with a predetermined depth in the first substrate 10. The depth of the ion implantation layer 12 is increased in proportion to the size of an electric energy. At this point, based on the ion implantation layer 12, the first substrate 10 remains at the lower portion, and an active layer 14 may be formed at the upper portion in order for manufacturing a thin film transistor that will be mentioned later.

Referring to FIG. 2, a gate insulation layer 16 and a gate electrode 18 are formed on the active layer 14. The gate insulation layer 16 includes a silicon oxide layer. The gate electrode 18 includes a metal layer of excellent conductivity and a conductive layer formed of poly silicon doped with conductive impurity. For example, the gate electrode 18 includes at least one barrier metal layer among titanium, titanium nitride, tungsten, and silicide tungsten, which prevents diffusion during a following thermal treatment of a high temperature.

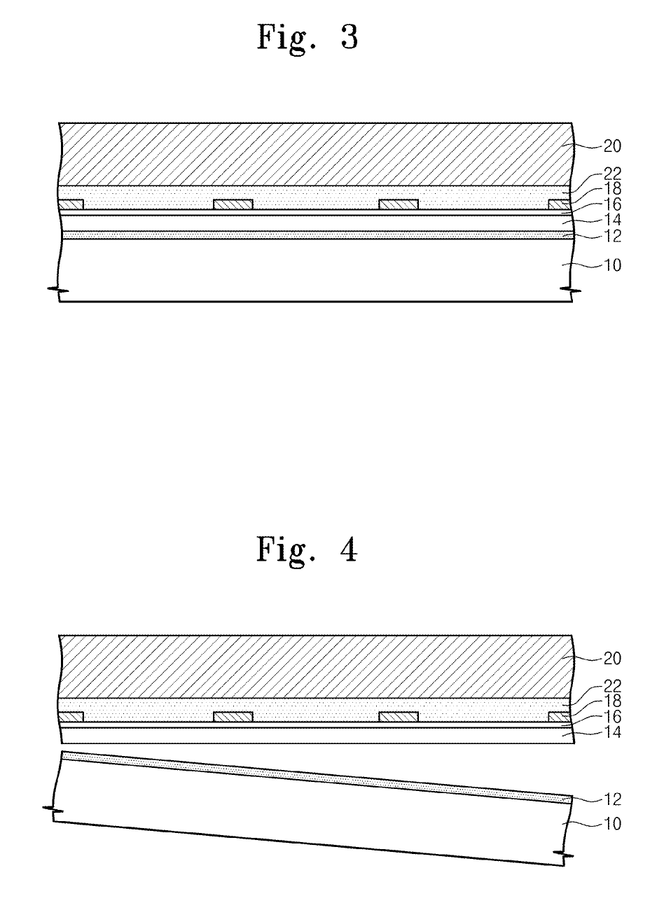

Referring to FIG. 3, a second substrate 20 of a glass material is bonded on the upper surface of the active layer 14. The second substrate 20 of a glass material and the active layer 14 may be strongly bonded by the first insulation layer 22 formed of a silicon oxide layer. For example, the first insulation layer 22 is formed on the second substrate 20 first, and the first insulation layer 22 and the active layer 14 are chemically bonded at about 200° C. The first insulation layer 22 may include a silicon oxide layer formed through a chemical vapor deposition (CVD) method. At this point, the first insulation layer 22 formed of a silicon oxide layer with a predetermined thickness is formed on the active layer 14 in order to remove a step caused by the gate electrode 18 formed on the active layer 14, and then second substrate 20 is bonded thereon.

Referring to FIG. 4, the active layer 14 is separated from the first substrate 10. Here, the active layer 14 is laminated from the first substrate 10 when the first substrate 10 is heated at a high temperature of about 600° C. and hydrogen ions of the ion implantation layer 12 bubble. A technique for separating the active layer 14 from the first substrate 10 based on the ion implantation layer 12 is typically known as ion-cut, smart-cut, and soft-cut.

According to the manufacturing method of the semiconductor device according to the first embodiment, since the gate insulation layer 16 and the gate electrode 18 are formed on the active layer 14 before a high temperature process such as ion cut is performed, a high-performance device can be manufactured.

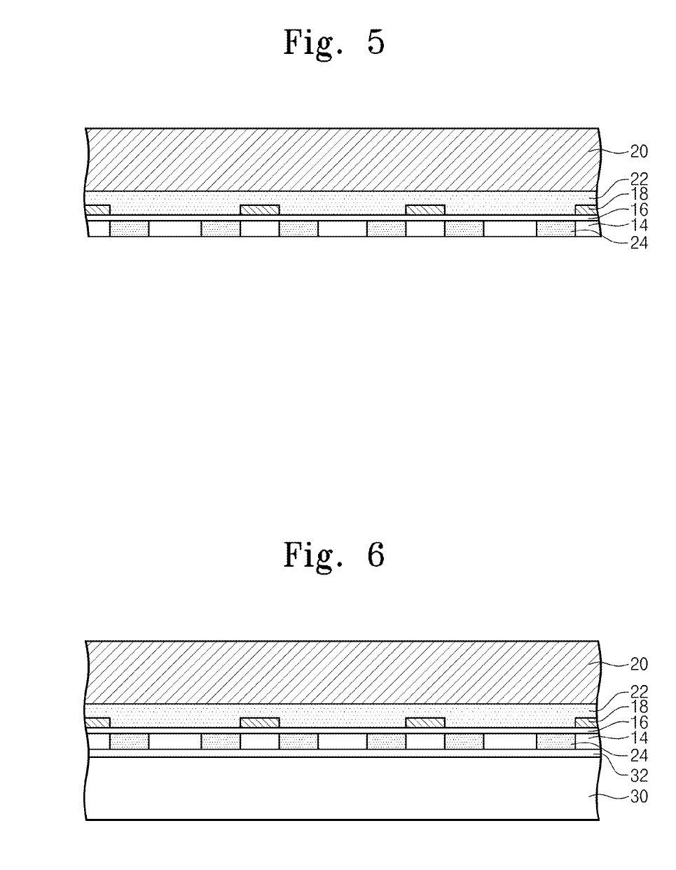

Referring to FIG. 5, a conductive impurity is ion-implanted on the active layer 14 at both sides of the gate electrode 18 to form conductive impurity regions 24. Here, the conductive impurity includes a p-type impurity of Group 3 elements such as B, Ga, In, etc. and an n-type impurity of Group 5 elements such as Sb, As, P, etc. For example, the conductive impurity regions 24 are formed by using a photoresist pattern as an ion implantation mask on the active layer 14 bonded on the second substrate 20 and ion-implanting the conductive impurity on the bottom of the active layer 14.

Referring to FIG. 6, the active layer 14 bonded on the second substrate 20 is bonded on a third substrate 30 of a plastic material. For example, the active layer 14 and the third substrate 30 are bonded by an adhesive layer 32. The adhesive layer 32 includes a petrochemical adhesive such as epoxy, silicon, hot melt, polymer, PVAc, etc. The third substrate 30 may be formed of a transparent plastic material in order to realize a flexible display that uses a thin film transistor on the active layer 14 as a switching device.

Accordingly, the manufacturing method of a semiconductor device according to the first embodiment can complete a manufacturing process of a high temperature before the third substrate 30 of a plastic material, which can cause impurity pollution during a high temperature process, is bonded.

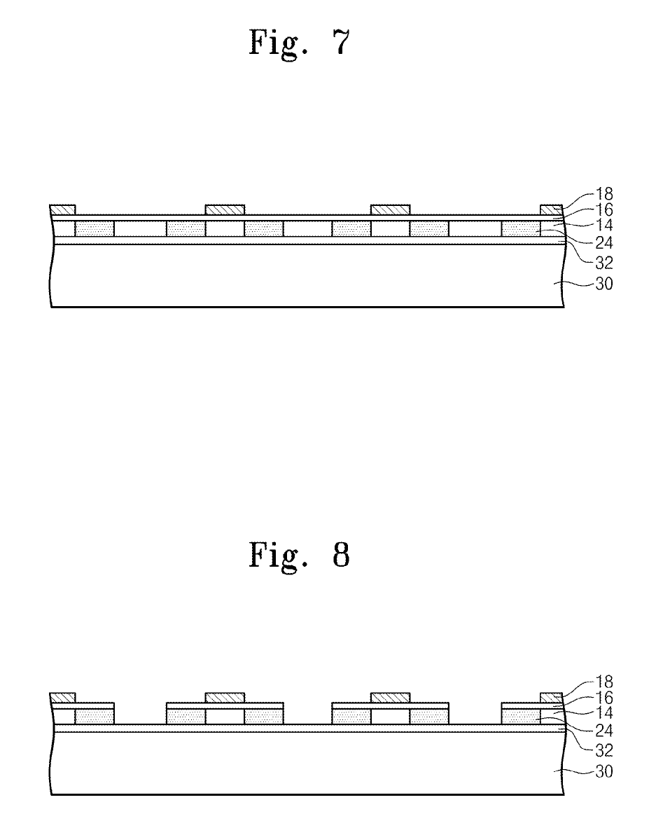

Referring to FIG. 7, the second substrate 20 and the first insulation layer 22 on the gate electrode 18 are removed. The second substrate 20 of a glass material and the first insulation layer 22 of a silicon oxide layer may be removed through wet etch or dry etch, which uses HF as a source.

Referring to FIG. 8, an island process is performed on the active layer 14 bonded on the third substrate 30. Here, the island process separates a plurality of thin film transistors formed on the active layer 14. For example, a plurality of thin film transistors formed on the third substrate 30 may be arranged in a matrix.

Additionally, the active layer 14 is formed of an opaque single crystal silicon material. At this point, most of the active layer 14 except for a portion where a transistor including gate, source, and drain electrodes is formed is removed through the island process to increase the transmittance in the flexible display including the third substrate 30 of a transparent plastic material.

Accordingly, the island process removes the unnecessary active layer 14 except for a region of the active layer 14 where a thin film transistor is formed, and may be a separation process for separating thin film transistors on the third substrate 30.

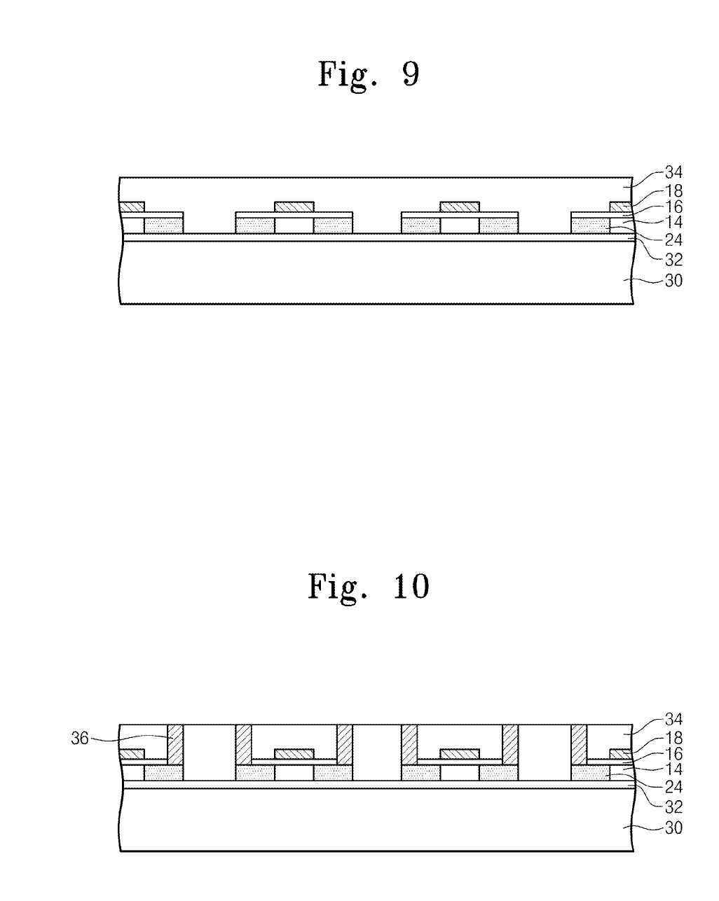

Referring to FIG. 9, a second insulation layer 34 is formed on the gate electrode 18 and the gate insulation layer 14. The second insulation layer 34 may be formed on an entire surface of the third substrate 30 including the gate electrode 18 and the tops of the gate insulation layer 16. The tops are exposed at both sides of the gate electrode 18. Additionally, the second insulation layer 34 may include a silicon oxide layer formed through a CVD method.

Referring to FIG. 10, after a contact hole is formed by removing the second insulation layer 34 on the conductive impurity regions 24 at both sides of the gate electrode 18, a contact plug 36 of a conductive metal layer is formed in the contact hole. The contact plug 36 penetrates through the second insulation layer 34 to be electrically connected to the conductive impurity region 24. For example, the contact plug 36 is formed in the contact hole by forming a conductive metal layer on an entire surface of the third substrate 30 having the contact hole through a sputtering method and evenly removing the conductive metal layer on the second insulation layer 34.

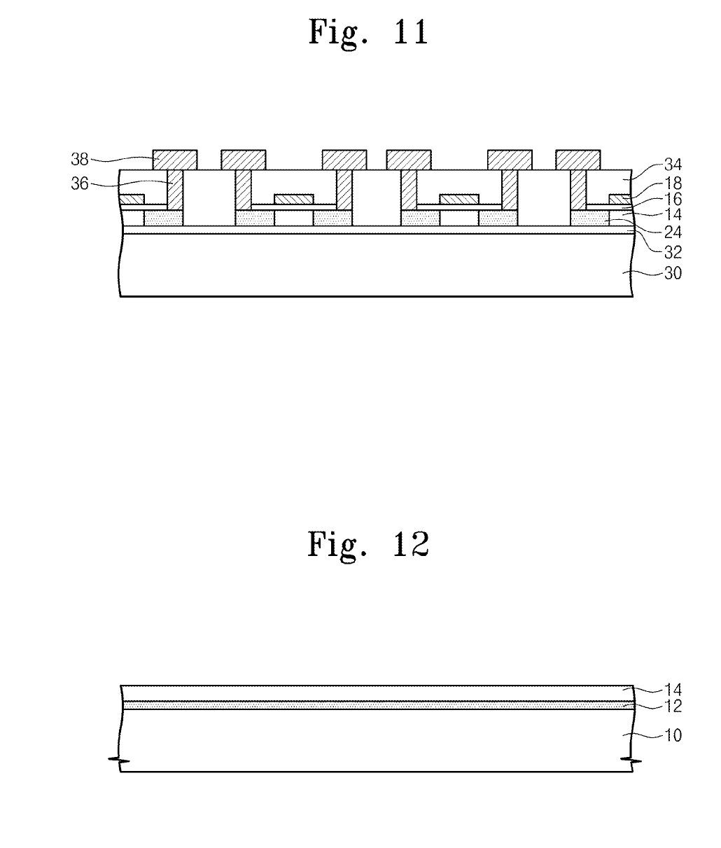

Referring to FIG. 11, source and drain electrodes 38 are formed on the contact plug 36. The source and drain electrodes 38 may be separately patterned on the contact plug 36 through a photolithography process, after a conductive metal layer is formed on an entire surface of the third substrate 30 where the contact plug 36 is exposed. Accordingly, the contact plug 36 and the source and drain electrodes 38 may be formed at once through the same process if the second insulation layer 34 is thin. For example, after a conductive metal layer is formed on the third substrate 30 where the conductive impurity regions 24 are exposed through the contact hole formed in the second insulation layer 34, a patterning process is performed to simultaneously form the contact plug 36 and the source and drain electrodes 38.

The source and drain electrodes 38 on the second insulation 34 may be electrically connected to the conductive impurity regions 24 of the active layer 14 through the contact plug 36. The gate electrode 18 is formed on a channel region between the conductive impurity regions 24 of the active layer 14 in the second insulation layer 34.

According to the manufacturing method of the semiconductor device according to the first embodiment, since a single crystal silicon thin film transistor (which can provide a high-speed operation after a thermal treatment process of a high temperature is completed on the first substrate 10 and the second substrate 20) can be manufactured in the third substrate 30 of a plastic material, an yield rate of production can be improved.

Although not shown, a third insulation layer may be formed on the source and drain electrodes 38. Additionally, it is possible to form a transparent electrode that penetrates through the third insulation layer to be electrically connected to one of the source and drain electrodes 38 and is separated in a matrix on the third insulation layer.

FIGS. 12 to 22 are manufacturing sectional views illustrating a manufacturing method of a semiconductor device according to a second embodiment of the present invention.

Referring to FIG. 12, according to the manufacturing method of the semiconductor device, hydrogen ions are ion-implanted on a first substrate 10 of single crystal silicon in order to form an ion implantation layer 12 in the first substrate 10. The ion implantation layer 12 may be formed in the first substrate 10 with a predetermined depth through an implanter. At this point, the depth of the ion implantation layer 12 in the first substrate 10 may be determined in proportion to the size of an electric energy, which is applied to hydrogen ions in the implanter. Accordingly, an active layer 14, which will be used for manufacturing a thin film transistor later, may be formed on the ion implantation layer 12 disposed on the first substrate 10.

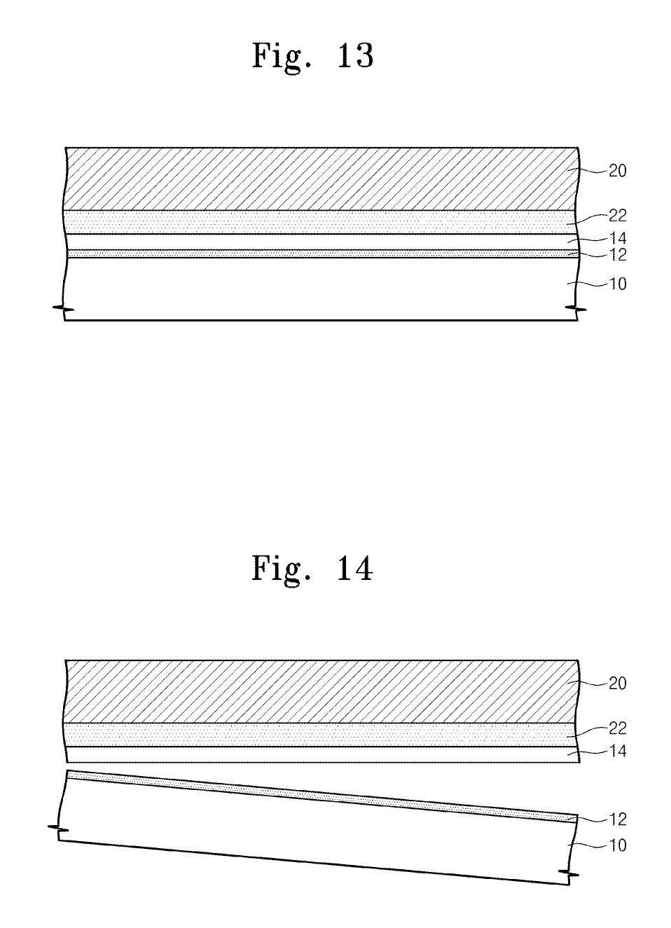

Referring to FIG. 13, a second substrate 20 of a glass material is bonded on the top surface of the active layer 14. The second substrate 20 of a glass material and the active layer 14 may be strongly bonded by a first insulation layer 22 of a silicon oxide layer. For example, the first insulation layer 22 and the active layer 14 are chemically bonded at about 200° C. The first insulation layer 22 may include a silicon oxide layer formed through a CVD method.

Referring to FIG. 14, the active layer 14 is separated from the first substrate 10. Here, the active layer 14 is laminated from the first substrate 10 when the first substrate 10 is heated at a high temperature of about 600° C. and hydrogen ions of the ion implantation layer 12 bubble. A technique for separating the active layer 14 from the first substrate 10 based on the ion implantation layer 12 is typically known as ion-cut, smart-cut, and soft-cut. Although not illustrated in the drawing, a process for polishing the bottom of the active layer 14 is additionally performed by performing chemical mechanical polishing (CMP) on the bottom of the ion implantation layer 12.

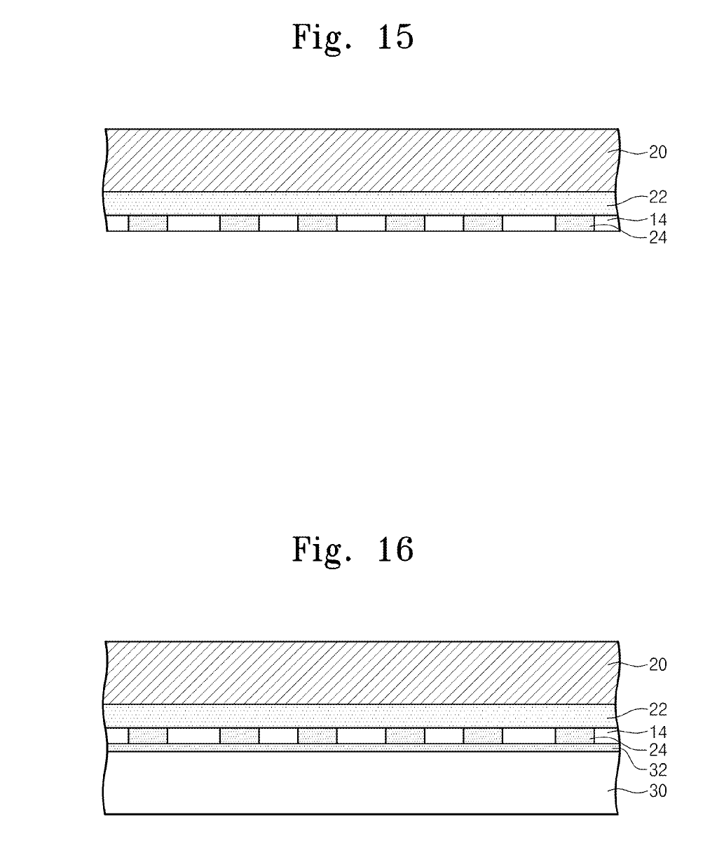

Referring to FIG. 15, a conductive impurity is ion-implanted on the active layer 14 at both sides of the gate regions to form conductive impurity region 24. Here, the conductive impurity includes a p-type impurity of Group 3 elements such as B, Ga, In, etc. and an n-type impurity of Group 5 elements such as Sb, As, P, etc. For example, the conductive impurity regions 24 are formed by using a photoresist pattern as an ion implantation mask on the active layer 14 bonded on the second substrate 20 and ion-implanting the conductive impurity on the bottom of the active region.

Accordingly, the manufacturing method of a semiconductor device according to the second embodiment forms the conductive impurity regions 24 on the active layer 14 after a high temperature process such as ion cut is completed. Therefore, a high performance device can be manufactured.

Referring to FIG. 16, the active layer 14 bonded on the second substrate 20 is bonded on a third substrate 30 of a plastic material. For example, the active layer 14 and the third substrate 30 are bonded by an adhesive layer 32. The adhesive layer 32 includes a petrochemical adhesive such as epoxy, silicon, hot melt, polymer, PVAc, etc. The third substrate 30 may be formed of a transparent plastic material in order to realize a flexible display that uses a thin film transistor on the active layer 14 as a switching device.

Accordingly, the manufacturing method of a semiconductor device according to the second embodiment can complete a manufacturing process of a high temperature before the third substrate 30 of a plastic material, which can cause impurity pollution during a high temperature process, is bonded.

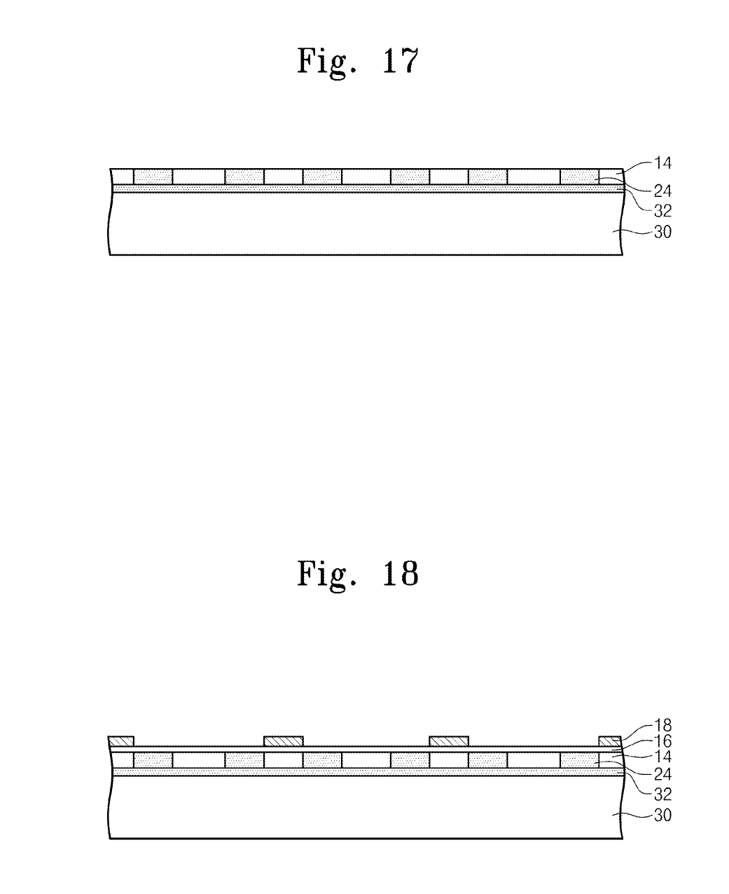

Referring to FIG. 17, the second substrate 20 and the first insulation layer 22 on the gate electrode 18 are removed. The second substrate 20 of a glass material and the first insulation layer 22 of a silicon oxide layer may be removed through wet etch or dry etch, which uses HF as a source.

Referring to FIG. 18, the gate insulation layer 16 and the gate electrode 18 are formed on the active layer 14. The gate insulation layer 16 includes a silicon oxide layer on an entire surface of the active layer 14. Furthermore, when the second substrate 20 is removed, the entire first insulation layer 22 is not removed, and thus the remaining first insulation layer 22 may be used as a gate insulation layer.

Additionally, when a conductive layer is formed on an entire surface of the active layer 14, the gate electrode 18 can be patterned by a photoresist in order to position the conductive layer separately on the active layer 14 between the conductive impurity regions 24. For example, the gate electrode 18 includes a conductive metal layer such as Au, Ag, Al, W, Cu, Ti, and Ta and a poly silicon layer doped with a conductive impurity.

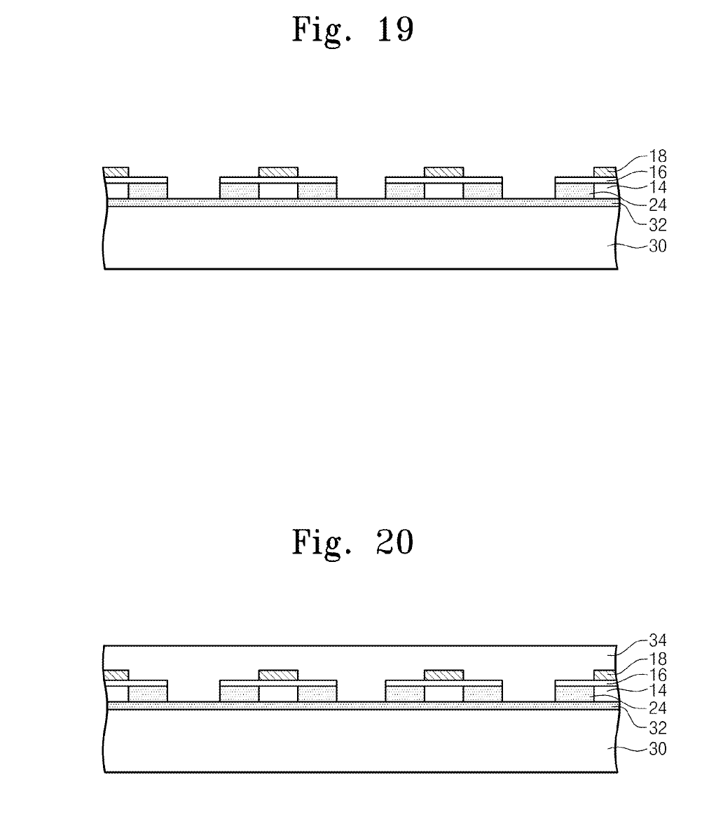

Referring to FIG. 19, an island process is performed on the active layer 14 bonded on the third substrate 30. Here, the island process separates a plurality of thin film transistors on the active layer 14. For example, a plurality of thin film transistors on the third substrate 30 may be arranged in a matrix.

Most of the active layer 14 except for a portion where a transistor including gate, source, and drain electrodes is formed is removed by the island process to increase the transmittance in the flexible display including the third substrate 30 of a transparent plastic material.

Accordingly, the island process removes the unnecessary active layer 14 except for a region of the active layer 14 where a thin film transistor is formed, and may be a separation process for separating thin film transistors on the third substrate 30.

Referring to FIG. 20, a second insulation layer 34 is formed on the gate electrode 18 and the active layer 14. The second insulation layer 34 may be formed on an entire surface of the third substrate 30 including the gate electrode and the top of the gate insulation layer 14. The top is exposed at both sides of the gate electrode 18. Additionally, the second insulation layer 34 may include a silicon oxide layer formed through a CVD method.

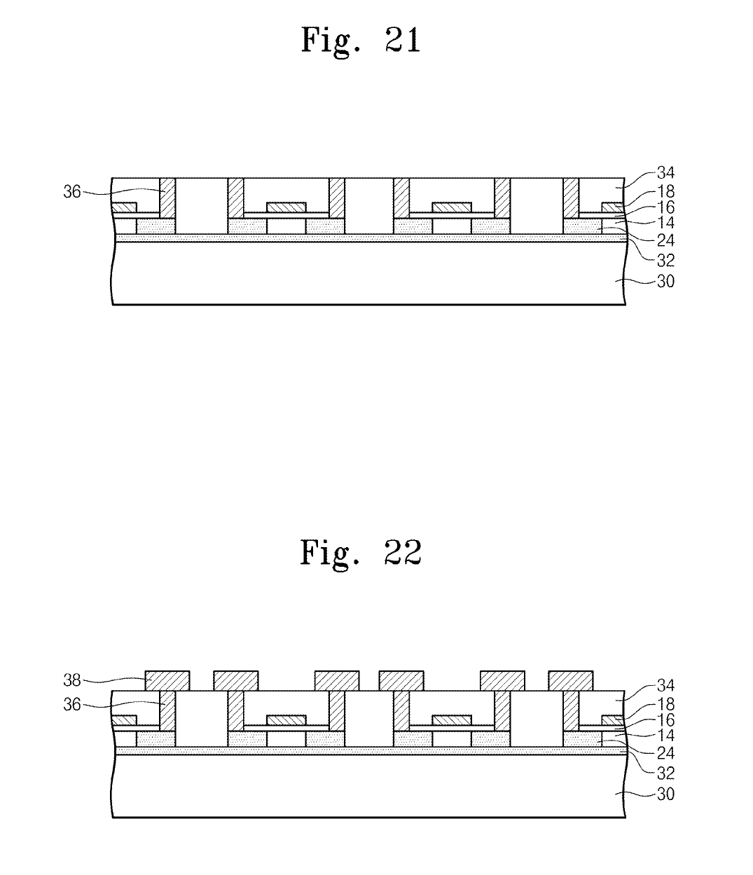

Referring to FIG. 21, after a contact hole is formed by removing the second insulation layer 34 on the conductive impurity regions 24 at both sides of the gate electrode 18, a contact plug 36 of a conductive metal layer is formed in the contact hole. The contact plug 36 penetrates through the second insulation layer 34 to be electrically connected to the conductive impurity regions 24. For example, the contact plug 36 is formed in the contact hole by forming a conductive metal layer on an entire surface of the third substrate 30 having the contact hole through a sputtering method and evenly removing the conductive metal layer on the second insulation layer 34.

Referring to FIG. 22, source and drain electrodes 38 are formed on the contact plug 36. The source and drain electrodes 38 may be separately patterned on the contact plug 36 through a photolithography process, after a conductive metal layer is formed on an entire surface of the third substrate 30 where the contact plug 36 is exposed. Accordingly, the contact plug 36 and the source and drain electrodes 38 may be formed by once through the same process if the second insulation layer 34 is thin. For example, after a conductive metal layer is formed on the third substrate 30 where the conductive impurity regions 24 are exposed through the contact hole formed in the second insulation layer 34, a patterning process is performed to simultaneously form the contact plug 36 and the source and drain electrodes 38.

According to the manufacturing method of the semiconductor device according to the second embodiment, since a single crystal silicon thin film transistor (which can provide a high-speed operation after a thermal treatment process of a high temperature is completed on the first substrate 10 and the second substrate 20) can be manufactured in the third substrate 30 of a plastic material, an yield rate of production can be improved.

Although not shown, a third insulation layer may be formed on the source and drain electrodes 38. Additionally, it is possible to form a transparent electrode that penetrates through the third insulation layer to be electrically connected to one of the source and drain electrodes 38 and is separated in a matrix on the third insulation layer.

As a result, according to the manufacturing methods of the semiconductor device according to the embodiments of the present invention, as mentioned above, since a thermal treatment process of a high temperature is completed before the thin film transistor is transferred into the third substrate of a plastic material, an yield rate of device production can be improved. It is apparent to those skilled in the art that these modified embodiments are realized without difficulties based on the technical idea of the present invention.

According to configuration of embodiments of the present invention, a yield rate of production can be increased by completing a manufacturing process of a thin film transistor on a third substrate of a plastic material.

Additionally, before an active layer of a single crystal silicon is transferred into a third substrate of a plastic material, a thermal treatment process of a high temperature is completed. Therefore, a yield rate of production can be maximized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A manufacturing method of a semiconductor device, the method comprising:
forming an active layer on a first substrate;
bonding a top surface of the active layer with a second substrate and separating the active layer from the first substrate;
forming conductive impurity regions corresponding to source and drain regions of the active layer bonded on the second substrate;
bonding a third substrate on a bottom surface of the active layer and removing the second substrate; and
forming a gate electrode on a top between the conductive impurity regions of the active layer bonded on the third substrate and forming source and drain electrodes on the conductive impurity regions.

2. The method of claim 1, wherein the forming of the active layer comprises forming an ion implantation layer of a predetermined depth in the first substrate.

3. The method of claim 2, further comprising forming the gate electrode on the active layer after the forming of the ion implantation layer.

4. The method of claim 3, further comprising forming the gate insulation layer between the active layer and the gate electrode.

5. The method of claim 3, wherein the gate electrode comprises titanium or titanium nitride.

6. The method of claim 2, wherein the separating of the active layer comprises performing a thermal treatment process on the ion implantation layer.

7. The method of claim 1, wherein the bonding of the top surface of the active layer with the second substrate comprises interposing a first insulation layer between the top surface of the active layer and the second substrate.

8. The method of claim 7, wherein the first insulation layer is not removed when the second substrate is removed and the remaining first insulation layer is used as a gate insulation layer.

9. The method of claim 1, wherein a bottom surface of the active layer and the third substrate are bonded using an adhesive layer.

10. The method of claim 1, further comprising islanding thin film transistors including the gate electrode, the source electrode, and the drain electrode, the gate electrode being disposed on the active layer on the third substrate.

11. The method of claim 10, further comprising forming a second insulation layer on the active layer and the third substrate.

12. The method of claim 11, further comprising forming a contact plug, the contact plug penetrating through the second insulation layer and connecting the conductive impurity regions and the source and drain electrodes.
